(19) United States
(12) Patent Application Publication
(10) Pub. No.: US 2013/0237011 A1
(43) Pub. Date: Sep. 12, 2013

(54) COMPOSITION FOR OXIDE SEMICONDUCTOR AND METHOD OF MANUFACTURING A THIN FILM TRANSISTOR SUBSTRATE USING THE SAME

(71) Applicants: SAMSUNG DISPLAY CO., LTD., Yongin-City (KR); KOREAN ADVANCED INSTITUTE OF SCIENCE AND TECHNOL, Daejeon (KR)

(72) Inventors: Yeon-Taek JEONG, Seoul (KR); Bo-Sung KIM, Seoul (KR); Doo-Hyoung LEE, Suwon-si (KR); Seung-Ho JUNG, Incheon (KR); Tae-Young CHOI, Seoul (KR); Doo-Na KIM, Seongnam-si (KR); Byeong-Soo BAE, Daejeon (KR); Chan-Woo YANG, Hwaseong-si (KR); Byung-Ju LEE, Gunpo-si (KR); Kang-Moon JO, Seoul (KR); Young-Hwan HWANG, Daejeon (KR); Jun-Hyuck JEON, Daejeon (KR)

(73) Assignees: KOREA ADVANCED INSTITUTE OF SCIENCE AND TECHNOLOGY, Daejeon (KR); SAMSUNG DISPLAY CO., LTD., Yongin-City (KR)

(21) Appl. No.: 13/679,311

(22) Filed: Nov. 16, 2012

(30) Foreign Application Priority Data
Mar. 9, 2012 (KR) 10-2012-0024418

(51) Int. Cl. C09D 1/00; H01L 29/66

(52) U.S. Cl. CPC C09D 1/00; H01L 29/66969
USPC 438/104; 106/286.1; 106/287.18

(57) ABSTRACT

A method of manufacturing a thin-film transistor substrate includes: applying a composition on a substrate to form a thin-film on the substrate, heating the thin-film, and patterning the thin-film to form an oxide semiconductor pattern. The composition includes a metal nitrate and water. The potential of hydrogen (pH) of the composition is about 1 to about 4.

### CROSS-REFERENCE TO RELATED APPLICATION

This application claims priority from and the benefit of Korean Patent Application No. 10-2012-0024418, filed on Mar. 9, 2012, which is incorporated by reference for all purposes as if set forth herein.

### BACKGROUND

1. Field

Exemplary embodiments relate to compositions that may be utilized in association with the manufacture of oxide semiconductors, and more particularly to water-based solvent compositions that may be utilized in association with the manufacture of thin-film transistors.

2. Discussion

Conventional thin-film transistors configured to drive a pixel in a display device typically include a gate electrode, a source electrode, a drain electrode, and an active pattern forming a channel between the source and drain electrodes. The active pattern may include amorphous silicon, polysilicon, an oxide semiconductor, and/or the like.

An oxide semiconductor may be manufactured via low-temperature processing techniques, may be easily enlarged, and typically exhibits relatively high electron mobility characteristics. Solution-based processing techniques utilized in the manufacture of oxide semiconductors may include selectively forming a thin film on a target area without strict control of growth conditions, unlike conventional vapor deposition techniques, which are usually subject to tightly controlled growth conditions. In this manner, solution-based manufacturing processes may be less complex and onerous, as well as more cost-effective than conventional vapor deposition techniques.

Environmental pollution associated with and potential human exposure to conventional solvents utilized in association with the manufacture of oxide semiconductors, such as alkoxyalcohol solvents, e.g., 2-methoxyethanol, are of concern. Therefore, there is a need for an approach that provides cost-effective, environmentally-friendly compositions for the manufacture of oxide semiconductors, such as water-based solvent compositions.

The above information disclosed in this Background section is only for enhancement of understanding of the background of the invention and, therefore, it may contain information that does not form any part of the prior art nor what the prior art may suggest to a person of ordinary skill in the art.

### SUMMARY

Exemplary embodiments provide environmentally-friendly, water-based solvent compositions that may be utilized in association with the manufacture of oxide semiconductors.

Exemplary embodiments also provide a method to manufacture a thin-film transistor substrate using such environmentally-friendly, water-based solvent compositions.

Additional aspects will be set forth in the detailed description which follows and, in part, will be apparent from the disclosure, or may be learned by practice of the invention.

According to exemplary embodiments, a composition for an oxide semiconductor includes a metal nitrate and water. The potential of hydrogen (pH) of the composition is about 1 to about 4.

According to exemplary embodiments, a method of manufacturing a thin-film transistor includes: applying a composition on a substrate to form a thin-film on the substrate; heating the thin-film; and patterning the thin-film to form an oxide semiconductor pattern. The composition includes a metal nitrate and water. The potential of hydrogen (pH) of the composition is about 1 to about 4.

According to exemplary embodiments, a composition for an oxide semiconductor includes a water-based solvent and, as such, toxicity associated with manufacturing processes utilizing the composition may be reduced.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further is understanding of the invention and are incorporated in and constitute a part of this specification, illustrate exemplary embodiments of the invention, and together with the description serve to explain the principles of the invention.

FIG. 1 is a plan view of a display apparatus including a plurality of thin-film transistors, according to exemplary embodiments.

FIG. 2 is an enlarged plan view of a circuit transistor and the pixel transistor of the display apparatus of FIG. 1, according to exemplary embodiments.

FIG. 3 is a cross-sectional view of the circuit transistor and the pixel transistor of FIG. 2 taken along sectional line I-I′, according to exemplary embodiments.

FIGS. 4A-4E illustrate a process for manufacturing the circuit transistor and the pixel transistor of FIG. 3, according to exemplary embodiments.

FIG. 5 is a graph of output drain current versus drain-source voltage of a first comparative thin-film transistor, according to exemplary embodiments.

FIG. 6 is a graph of output drain current versus gate voltage of the first comparative thin-film transistor, according to exemplary embodiments.

FIG. 7 is a graph of output drain current versus gate voltage of a second comparative thin-film transistor, according to exemplary embodiments.

### DETAILED DESCRIPTION OF EXAMPLE EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, is well-known structures and devices are shown in block diagram form in order to avoid unnecessarily obscuring various exemplary embodiments.

In the accompanying figures, the size and relative sizes of layers and/or regions may be exaggerated for clarity and descriptive purposes. Also, like reference numerals denote like elements.

When an element or layer is referred to as being “on,” “connected to,” or “coupled to” another element or layer, it may be directly on, directly connected to, or directly coupled to the other element or layer, or intervening elements or layers may be present. When, however, an element is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section that is discussed below may be termed a second element, component, region, layer, or section without departing from the teachings of the present invention.

Spatially relative terms, such as “beneath,” “below,” “lower,” “above,” “upper,” and/or the like, may be used herein for descriptive purposes and, thereby, to describe one element or feature's relationship to another element(s) or feature(s) as illustrated in the drawings. Spatially relative terms are intended to encompass different orientations of an apparatus in use or operation in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations) and, as such, the spatially relative descriptors used herein are to be interpreted accordingly.

The terminology used herein is for the purpose of describing particular embodiments only and is not intended to be limiting. As used herein, the singular forms “a,” “an,” and “the” are intended to include the plural forms as well, unless the context clearly indicates otherwise. Moreover, the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have is rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

According to exemplary embodiments, a composition utilized in association with manufacturing an oxide semiconductor includes a metal nitrate and water. A potential of hydrogen (pH) of the composition is about 1 to about 4, such as about 2 to about 3, e.g., about 2.5. It is noted that the water may be deionized water.

In exemplary embodiments, the metal nitrate may be a hydrate or an anhydrate. The metal nitrate may include at least one nitrate of one or more metals, such as, for example: lithium (Li), sodium (Na), potassium (K), rubidium (Rb), caesium (Cs), beryllium (Be), magnesium (Mg), calcium (Ca), strontium (Sr), barium (Ba), titanium (Ti), zirconium (Zr), hafnium (Hf), vanadium (V), yttrium (Y), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), zinc (Zn), aluminum (Al), gallium (Ga), indium (In), thallium (Tl), silicon (Si), germanium (Ge), tin (Sn), lead (Pb), phosphorous (P), arsenic (As), antimony (Sb), bismuth (Bi), lanthanum (La), and/or the like.

For instance, the metal nitrate may include: aluminum nitrate hydrate, indium nitrate hydrate, zinc nitrate 6-hydrate, zinc nitrate hydrate, yttrium nitrate hydrate, barium nitrate hydrate, lanthanum nitrate hydrate, strontium nitrate hydrate, indium nitrate anhydride, aluminum nitrate anhydride, zinc nitrate anhydride, and/or the like. In exemplary embodiments, the metal nitrate includes at least two different types (or kinds) of metal nitrates selected to control one or more electrical characteristics of an oxide semiconductor formed using the above-noted composition. For example, the metal nitrate may include aluminum nitrate hydrate and indium nitrate hydrate.

According to exemplary embodiments, the molar content of the metal nitrate in the composition may be about 0.001 M to about 10 M, e.g., about 0.01 M to about 1 M. It is noted, however, that when the molar content of the metal nitrate is less than about 0.001 M, it may be difficult to form a thin-film of sufficient thickness. To this end, it is also noted that when the molar content of the metal nitrate is more than about 10 M, one or more hydration reactions and/or condensing reactions may result and, thereby, reduce the stability of the composition. As such, the molar content of the metal nitrate may be about 0.001 M to about 10 M.

When combined, the constituent components of the composition may exhibit an aggregated potential of hydrogen (pH) of about 1 to about 4. It is noted that when the pH of the composition is greater than about 4, one or more chemical reactions may result in eduction, which may reduce one or more electrical characteristics of an oxide semiconductor formed is utilizing the composition.

According to exemplary embodiments, the composition may further include one or more acids or bases, which may be added to the composition to regulate the pH of the composition, e.g., regulate the pH to be about 1 to about 4. For instance, the one or more acids or bases may include hydrochloric acid, nitric acid, sulfuric acid, acetic acid, ammonium hydroxide, potassium hydroxide, sodium hydroxide, and the like. It is contemplated that any combination of one or more acids, one or more bases, or one or more acids and one or more bases may be utilized.

In exemplary embodiments, the composition may further include a solution stabilizer. For instance, the solution stabilizer may be or include one or more of an alcohol amine compound, an alkyl ammonium hydroxide compound, an alkyl amine compound, a ketone compound, and/or the like. In exemplary embodiments, the solution stabilizer may be or include: monoethanol amine, diethanol amine, triethanol amine, monoisopropyl amine, N,N-methylethanol amine, aminoethylethanol amine, diethyleneglycole amine, N-t-butylethanol amine, tetramethylammonium hydroxide, methylamine, ethylamine, acetylacetone, and/or the like. It is contemplated that combination of solution stabilizers may be utilized.

The solution stabilizer may be utilized to increase the solubility of one or more components of the composition. It is noted that varying the solubility of one or more components of the composition may be implemented to control (or affect) the uniformity of a resultant thin-film formed utilizing the composition. As such, the content (or components) of the solution stabilizer may vary depending on the contents and kinds of other components forming the composition. For example, the content percent by weight of the solution stabilizer may be from about 0.01% by weight to about 30% by weight of the total weight of the composition. In is this manner, the solution stabilizer may efficiently increase solubility, as well as the coating ability of the composition. It is noted, however, that the electrical characteristics of a resultant thin-film component (e.g., oxide semiconductor) manufactured utilizing the composition may be controlled without utilizing one or more solution stabilizers and, therefore, the composition may not include one or more solution stabilizers, which may lower the toxicity of the resultant composition.

In exemplary embodiments, since the above-noted composition may include a water-based solvent, the toxicity of the composition may be reduced.

According to exemplary embodiments, the composition may be utilized to manufacture one or more components of, for instance, a display device. For instance, the composition may be utilized in association with the formation of one or more thin-film transistor components of a self-emissive or non-self-emissive display device, e.g., a cathode ray tube (CRT) display device, an electrophoretic display (EPD) device, an electrowetting display (EW) device, a plasma display panel (PDP) device, an organic light emitting diode (OLED) display device, a field emission display (FED) device, and the like.

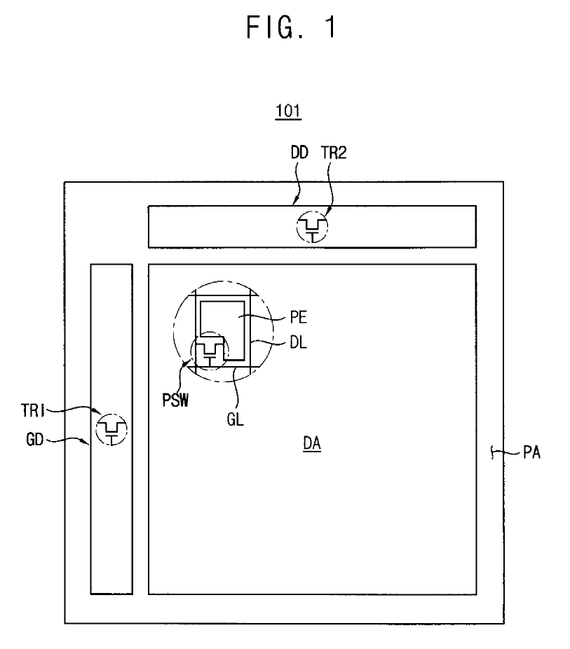

FIG. 1 is a plan view of a display apparatus including a plurality of thin-film transistors, according to exemplary embodiments. Although exemplary embodiments are described in association with the formation of thin-film transistor components of a display device, the previously described composition may be utilized in association with the formation of other components and devices, such as in association with thin-film transistors of a memory device, computing device, telephony device, etc.

As shown, the display apparatus includes a display substrate 101, a gate driver GD, and a data driver DD. The gate driver GD and the data driver DD are formed in a peripheral is area PA of the display substrate 101. In this manner, the display substrate 101 may include a display area DA surrounded by the peripheral area PA. The display area includes a plurality of pixel parts, as will become more apparent below. While specific reference will be made to this particular implementation, it is contemplated that the display apparatus may embody many forms and include multiple and/or alternative components or features. For example, it is contemplated that the components of the display apparatus may be combined, located in separate structures, and/or separate locations.

In exemplary embodiments, each respective pixel part may include a pixel transistor PSW and a pixel electrode PE connected to the pixel transistor PSW, which may be provided in association with one or more other components. The pixel transistor PSW may be connected to a gate line GL and a data line DL, which may be at least partially disposed in the display area DA. In this manner, the gate driver GD may be configured to provide a gate driving signal to the pixel part and, as such, may include a plurality of first circuit transistors TR1 for this purpose. The data driver DD may be configured to provide a data driving signal to the pixel part and, as such, may include a plurality of second circuit transistor TR2. It is noted that the pixel transistor PSW, the first circuit transistors TR1, and the second circuit transistors TR2 may be referred to as thin-film transistors.

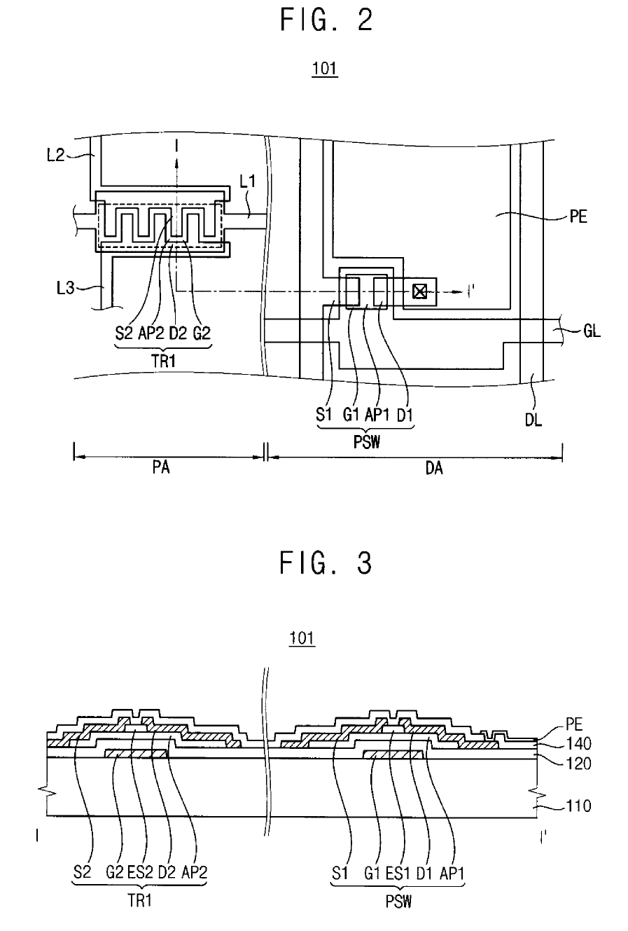

According to exemplary embodiments, one or more pixel transistors PSW, first circuit transistors TR1, and/or second circuit transistors TR2 may be manufactured utilized the previously described composition, which is described in more detail in association with FIGS. 2-4E. It is noted that since the second circuit transistors TR2 may be configured substantially same as the first circuit transistors TR1 (except, however, for an associated signal line connected thereto), duplicative explanation of the second circuit transistors TR2 will be omitted to avoid is obscuring exemplary embodiments described herein.

FIG. 2 is an enlarged plan view of a circuit transistor and a pixel transistor of the display apparatus of FIG. 1, according to exemplary embodiments. FIG. 3 is a cross-sectional view of the circuit transistor and the pixel transistor of FIG. 2 taken along sectional line I-I′.

As seen in FIGS. 2 and 3, the pixel transistor PSW includes a pixel gate electrode G1 connected to the gate line GL, a pixel source electrode S1 connected to the data line DL, a pixel drain electrode D1 spaced apart from the pixel source electrode S1, and a first semiconductor pattern AP1.

At least respective portions of the first semiconductor pattern AP1 may be overlapped by at least a portion of the pixel gate electrode G1 and the pixel drain electrode and, as such, may be disposed on the corresponding portions of the pixel gate electrode G1 and the pixel drain electrode D1. In exemplary embodiments, the first semiconductor pattern AP1 may be or include an oxide semiconductor. For example, the first semiconductor pattern AP1 may include a multi-component semiconductor, including indium zinc oxide, indium aluminum oxide, indium zinc tin oxide, and/or the like.

As previously mentioned, at least a portion of the pixel source electrode S1 and at least a portion of the pixel drain electrode D1 may be disposed on respective portions of the first semiconductor pattern AP1. A first etch stopper ES1 may be disposed on the first semiconductor pattern AP1, which may be configured to prevent the first semiconductor pattern AP1 from being exposed by a gap disposed between the pixel source electrode S1 and the pixel drain electrode D1. To this end, the first etch stopper ES1 may further be configured to prevent the first semiconductor pattern AP1 from being damaged when the pixel source electrode S1 and the pixel drain electrode D1 are being formed. As such, the pixel source electrode S1 and the pixel is drain electrode D1 may partially overlap respective portions of the first semiconductor pattern AP1. It is noted; however, that the first etch stopper ES1 may be omitted as desired.

In exemplary embodiments, the pixel source electrode S1 may overlap a first end portion of the first semiconductor pattern AP1, whereas the pixel drain electrode D1 may overlap a second end portion of the first semiconductor pattern AP1. To this end, an ohmic contact layer need not be formed between the first semiconductor pattern AP1 and the pixel source electrode S1, nor between the first semiconductor pattern AP1 and the pixel drain electrode D1, since a contact resistance therebetween may be relatively low as compared to a contact resistance associated with a thin-film transistor including an amorphous silicon channel. It is contemplated; however, that one or more ohmic contacts or ohmic contact layers may be provided to minimize a contact resistance between the pixel source electrode S1 and the first semiconductor pattern AP1 and between the drain electrode D1 and the first semiconductor pattern AP1, respectively.

Accordingly, the pixel drain electrode D1 is connected to (e.g., contacts) the pixel electrode PE, such that the pixel transistor PSW is connected to the pixel electrode PE.

In exemplary embodiments, The first circuit transistor TR1 includes a circuit gate electrode G2 connected to a control signal line L1, a circuit source electrode S2 connected to an input signal line L2, a circuit drain electrode D2 connected to an output signal line L3, a second semiconductor pattern AP2, and a second etch stopper ES2 partially covering the second semiconductor pattern AP2. The second semiconductor pattern AP2 may be formed from the same layer as the first semiconductor pattern AP1. In this manner, the second semiconductor pattern AP2 may be formed in association with the formation of the first semiconductor pattern AP1, such as in association with one or more of the same manufacturing processes. To this end, it is noted that the configuration of the first circuit transistor TR1 is substantially similar to the is configuration of the pixel transistor PSW, except that the first circuit transistor TR1 is disposed in the peripheral area PA and connected to one or more different signal lines. As such, duplicative explanation of the various components of the first circuit transistor TR1 are omitted to avoid obscuring exemplary embodiments described herein.

The display substrate 101 may further include a base substrate 110, a gate insulation layer 120, and a passivation layer 140. The gate insulation layer 120 is disposed on the base substrate 110 upon which the pixel gate electrode G1 and the circuit gate electrode G2 are disposed. In this manner, the gate insulation layer 120 may be configured to cover the pixel gate electrode G1 and the circuit gate electrode G2.

According to exemplary embodiments, the gate insulation layer 120 may include one or more layers, such as, for instance, a nitride layer and/or an oxide layer. The passivation layer 140 may be disposed on and arranged to cover the pixel source electrode S1, the pixel drain electrode D1, the circuit source electrode S2, and the circuit drain electrode D2. In this manner, the he passivation layer 140 may also be disposed on the gate insulation layer 120 and, thereby, configured to cover the gate insulation layer 120. To this end, the passivation layer 140 may include one or more layers, such as, for example, a nitride layer and/or an oxide layer.

The pixel electrode PE is disposed on the passivation layer 140; however, the pixel electrode PE contacts the pixel drain electrode D1 via a contact hole (or via) formed through the passivation layer 140.

Although not illustrated, a buffer layer may be disposed between the pixel gate electrode G1 and the base substrate 110 and, thereby, also between the circuit gate electrode G2 and the base substrate 110. The buffer layer may be utilized to increase adhesion between the pixel transistor PSE and the base substrate 110 and between the first circuit transistor TR1 and is the base substrate 110. Furthermore, while not illustrated, one or more planarization layers might be provided to enable a planar (or substantially planar) upper surface.

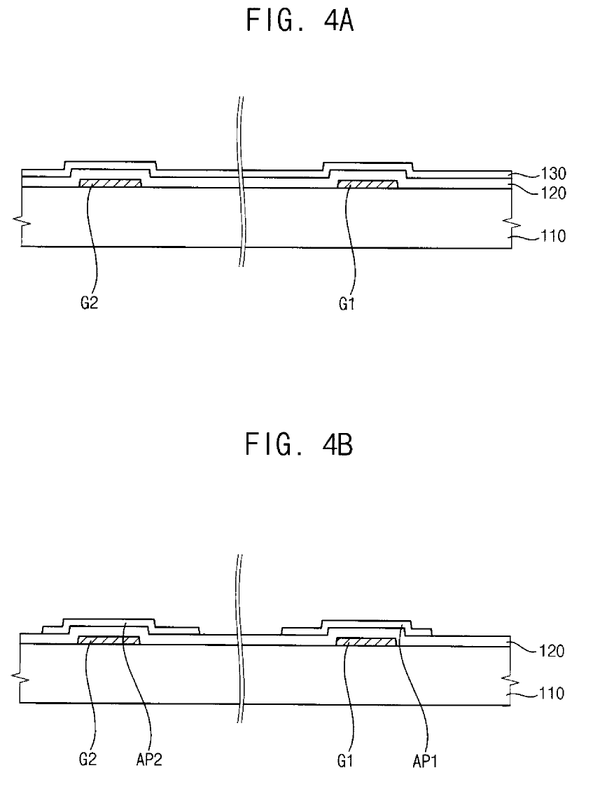

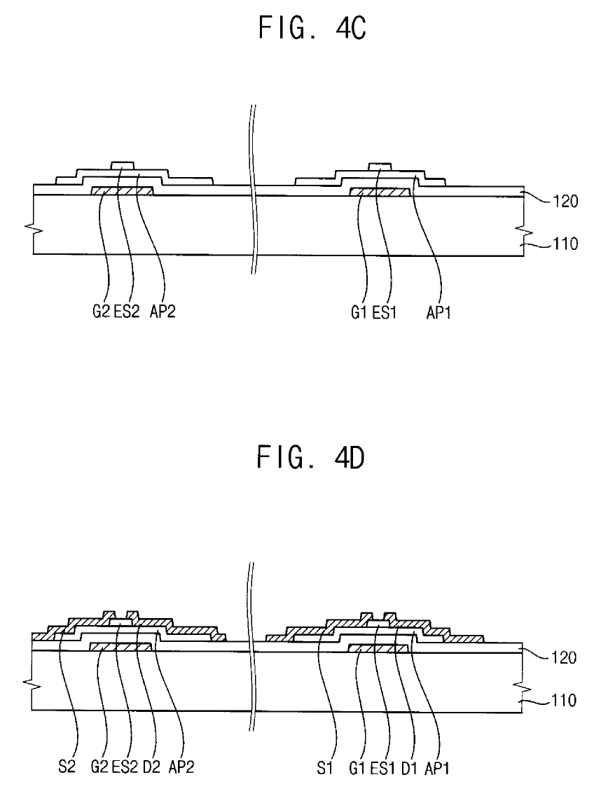

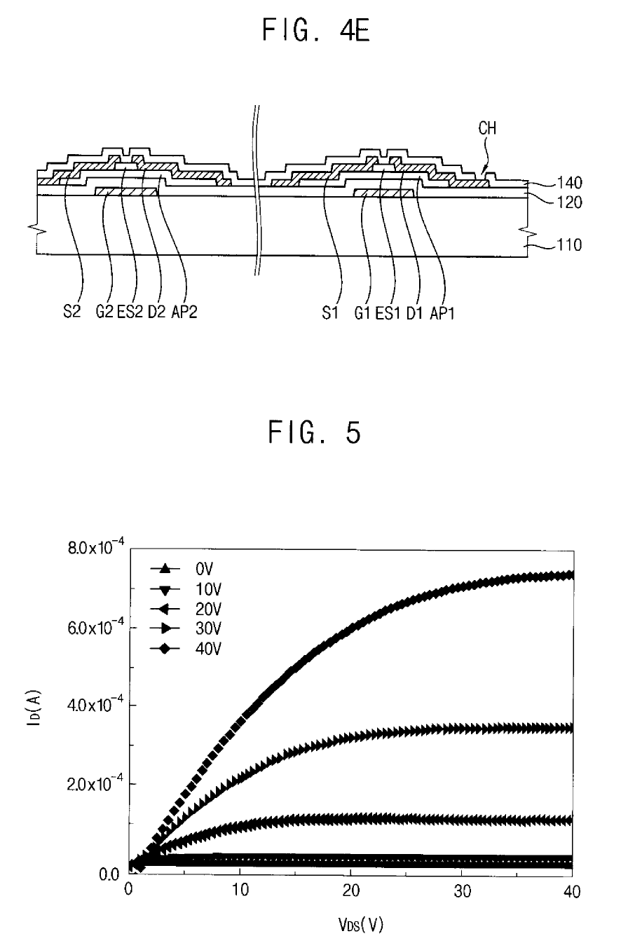

As previously mentioned, since then pixel transistor PSW, the first circuit transistor TR1, and the second circuit transistor TR2 may be formed from the same layer of display substrate 101, these components may be manufactured in one or more of the same manufacturing processes. FIGS. 4A-4E illustrate a process for manufacturing the circuit transistor and the pixel transistor of FIG. 3, according to exemplary embodiments.

As seen in FIG. 4A, the pixel gate electrode G1 and the circuit gate electrode G2 may be formed on the base substrate 110 via one or more suitable manufacturing techniques. It is noted that the base substrate 110 may be or include a glass substrate, a soda line substrate, a flexible plastic substrate, and/or the like.

The gate insulation layer 120 may be formed on the base substrate 110, upon which the pixel gate electrode G1 and the circuit gate electrode G2 are disposed. In this manner, the previously described composition may be applied (e.g., coated) on the gate insulation layer 120 to form a semiconductor layer 130. To this end, it is noted that the application of the composition on the gate insulation layer 120 is not limited to any specific manufacturing process and, therefore, may be formed via, for instance, spin coating, dip coating, bar coating, screen printing, slide coating, roll coating, slit coating, spray coating, dip-penning, nano-dispensing, inkjet printing, and/or the like.

Accordingly, one or more heating (e.g., baking, annealing, etc.) processes may be performed in association with the formation of the semiconductor layer 130, such as after the thin-film is disposed on the gate insulation layer 120. For instance, the one or more heating processes may be performed at about 10° C. to about 500° C. It is also contemplated that the one is or more heating processes may be performed at one or more temperatures ranging from about 100° C. to about 500° C.

Adverting to FIG. 4B, the semiconductor layer 130 may be patterned to form the first and second semiconductor patterns AP1 and AP2. Any suitable patterning technique may be utilized, such as, for example, via one or more photolithography and etching processes.

Referring to FIG. 4C, the first and second etch stoppers ES1 and ES2 may be formed on the first and second semiconductor patterns AP1 and AP2, respectively. The first and second etch stoppers ES1 and ES2 may partially cover respective portions of the first and second semiconductor patterns AP1 and AP2. To this end, it is again noted that the first and second etch stoppers ES1 and ES2 may be configured to prevent the first and second semiconductor patterns AP1 and AP2, respectively, from being exposed after the source electrodes S1 and S2 and the drain electrodes D1 and D2 are formed, as will become more apparent below. Further, the first and second etch stoppers ES1 and ES2 may be configured to prevent damage to the first and second semiconductor patterns AP1 and AP2 during and after one or more manufacturing processes. In exemplary embodiments, the first and second etch stoppers ES1 and ES2 may be manufactured from, for instance, silicon oxide, silicon nitride, silicon oxide nitride, and/or the like.

Adverting to FIG. 4D, the pixel source electrode S1, the pixel drain electrode D1, the circuit source electrode S2, and the circuit drain electrode D2 may be formed on the base substrate 110 that, at this point, includes the first and second semiconductor patters AP1 and AP2, upon which the first and second etch stoppers ES1 and ES2 are disposed. It is noted that the pixel source electrode S1, the pixel drain electrode D1, the circuit source electrode S2, and the circuit drain electrode D2 may be manufactured from a similar material and, as such, one or is more of these components may be contiguously formed as part of a metallization layer that is subsequently patterned to form the resultant structures. It is, of course, contemplated that any suitable manufacturing technique may be utilized to form the pixel source electrode S1, the pixel drain electrode D1, the circuit source electrode S2, and the circuit drain electrode D2. In this manner, respective portions of the source pixel electrode Si and source drain electrode D1 may be disposed and, thereby, arranged to overlap at least corresponding portions of the first semiconductor pattern AP1 and at least corresponding portions of the first etch stopper ES1. Similarly, respective portions of the circuit source electrode S2 and the circuit drain electrode D2 may be disposed and, thereby, arranged to overlap at least corresponding portions of the second semiconductor pattern AP2 and at least corresponding portions of the second etch stopper ES2. Accordingly, the pixel transistor PSW and the first circuit transistor TR1 may be formed.

In exemplary embodiments, the pixel source electrode S1, the pixel drain electrode D1, the circuit source electrode S2, and the circuit drain electrode D2 may be manufactured from, for instance, molybdenum, copper, aluminum, and/or the like. As such, any combination of these materials and/or other materials is contemplated. To this end, it is also noted that the above-noted metallization layer may include one or more layers, at least one of which may include one or more of the above-noted materials.

With reference to FIGS. 3 and 4E, the passivation layer 140 may be formed on the base substrate 110 at least including the pixel source electrode S1, the pixel drain electrode D1, the circuit source electrode S2, and the circuit drain electrode D2. In exemplary embodiments, one or more portions of the passivation layer 140 may be removed (e.g., patterned) to form a contact hole (or via) CH. As such, the pixel electrode PE may be formed on the passivation layer 140 and disposed to contact at least a portion of the pixel drain electrode D1 via contact hole CH. is In this manner, the display substrate 101 of FIGS. 1-3 may be manufactured.

According to exemplary embodiments, the previously described composition may be utilized in association with the formation of an oxide semiconductor and since the composition may include a water-based solvent, not only can the composition be less toxic, but the resulting devices incorporating components formed utilizing the composition can be less toxic.

As previously noted, while exemplary embodiments have been described in association with the formation of a thin-film transistor of display device, it is contemplated that the thin-film transistor (or another component) formed utilizing the composition may be manufactured in association with other devices, such as any suitable consumer electronic device, e.g., a memory device, computing device, telephony device, etc.

Performance characteristics of thin-film transistors formed utilizing the previously described composition are descried in association with various illustrative composition examples and associated performance characteristics data of FIGS. 5-7.

### Example 1

In a first implementation, about 0.0002 moles of aluminum nitrate hydrate and about 0.0038 moles of indium nitrate hydrate were added to about 20 ml of deionized water. The mixture was stirred for about 12 hours to prepare a composition that was subsequently utilized to form an oxide semiconductor. The pH of the resulting composition was about 2.8.

In this manner, the resulting composition was spin-coated on a substrate including a gate electrode formed from silicon doped with P-type impurities at a high concentration, and a silicon oxide insulation layer covering the gate electrode. The spin-coating was performed to apply a thin-film layer of the resulting composition having a thickness of about 1,000 Å. Thereafter, the substrate was heated for about 4 hours at about 25° C. to, thereby, form an aluminum indium oxide semiconductor layer. The length of the aluminum indium oxide semiconductor layer was about 100 μm and the width was about 1000 μm.

### Example 2

In a second implementation, about 0.0002 moles of aluminum nitrate hydrate and about 0.0038 moles of indium nitrate hydrate were added to about 20 ml of deionized water. The mixture was stirred for about 12 hours to prepare a composition that was subsequently utilized to form an oxide semiconductor. A solution of ammonium hydroxide was added to raise the pH of the composition to about 6.

Utilizing the same manufacturing process and dimensioning as described in association with the composition of Example 1, a thin-film transistor was formed utilizing the composition of Example 2.

Accordingly, each of the corresponding thin-film transistors of Examples 1 and 2 were subjected to performance tests to determine associated performance characteristics of the respective thin-film transistors and, thereby, of the compositions of Examples 1 and 2.

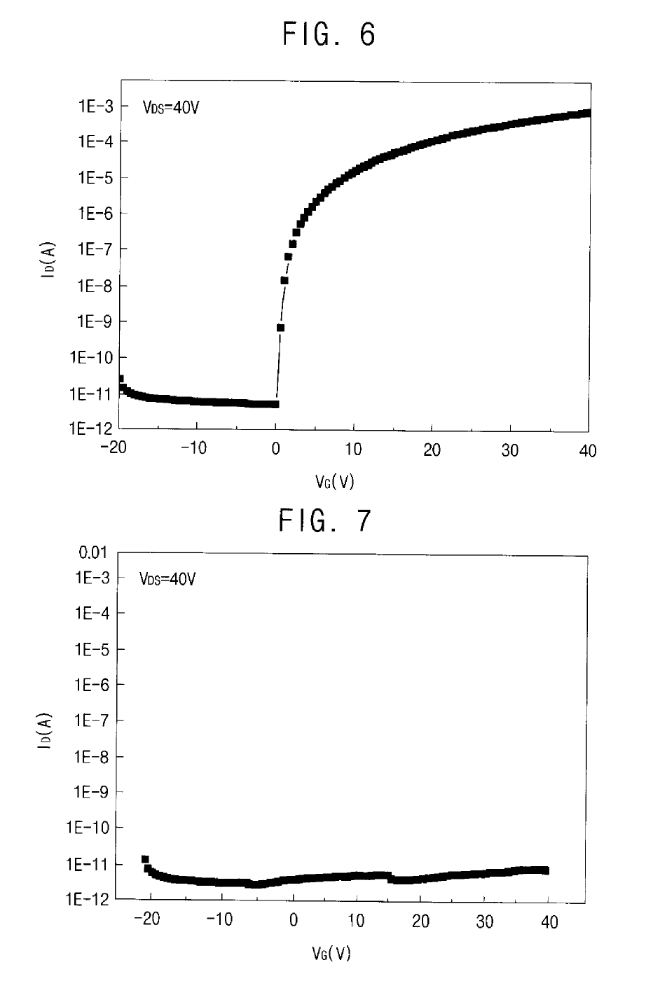

FIG. 5 is a graph of output drain current versus drain-source voltage of the thin-film transistor of Example 1. FIG. 6 is a graph of output drain current versus gate voltage of the thin-film transistor of Example 1. FIG. 7 is a graph of output drain current versus gate voltage of the thin-film transistor of Example 2.

As can be seen in FIG. 5, variation of output drain current I_{D} was measured with respect to drain-source voltage V_{DS} applied to a source-drain electrode of the thin-film transistor of Example 1 using an HP-4156A analyzer. In this manner, a plurality predetermined gate voltages Vg (e.g., about 0 V, about 10 V, about 20 V, about 30 V, and about 40 V) were applied is to a gate electrode of the thin-film transistor of Example 1 so that the output drain current I_{D} could be measured with respect to the drain-source voltage V_{DS}. The results are illustrated in FIG. 5.

Furthermore, variation of output drain current I_{D} was measured with respect to a gate voltage Vg applied to the gate electrode of the thin-film transistor of Example 1, which varied from about −20 V to about 40 V, while a drain-source voltage V_{DS} of about 40V was applied to the source-drain electrode of the thin-film transistor of Example 1. The results are illustrated in FIG. 6.

Similarly, variation of output drain current I_{D} was measured with respect to a gate voltage Vg applied to a gate electrode of the thin-film transistor of Example 2, which varied from about −20V to about 40V, while a drain-source voltage V_{DS} of about 40V was applied to a source-drain electrode of the thin-film transistor of Example 2. The results are illustrated in FIG. 7.

As can be seen in FIGS. 5 and 6, the thin-film transistor formed from the composition of Example 1, which includes deionized water as a solvent, is capable of operating as an effective transistor.

With reference to FIG. 7, the thin-film transistor formed from the composition of Example 2, which exhibited a pH of about 6, did not operate as an effective transistor. As such, it is apparent that the previously described composition should be pH controlled to ensure manufacture of suitable thin-film transistors.

While certain exemplary embodiments and implementations have been described herein, other embodiments and modifications will be apparent from this description. Accordingly, the invention is not limited to such embodiments, but rather to the broader scope of is the presented claims and various obvious modifications and equivalent arrangements.

What is claimed is:

1. A composition for an oxide semiconductor, comprising:
a metal nitrate; and
water,
wherein the potential of hydrogen (pH) of the composition is about 1 to about 4.

2. The composition of claim 1, wherein the metal nitrate comprises a hydrate or an anhydride.

3. The composition of claim 2, wherein the metal nitrate comprises at least two different metal nitrates.

4. The composition of claim 2, wherein the metal nitrate comprises at least one nitrate of a metal selected from the group consisting of Li, Na, K, Rb, Cs, Be, Mg, Ca, Sr, Ba, Ti, Zr, Hf, V, Y, Nb, Ta, Cr, Mo, W, Mn, Tc, Re, Fe, Ru, Os, Co, Rh, Ir, Ni, Pd, Pt, Cu, Ag, Au, Cd, Hg, B, Zn, Al, Ga, In, Tl, Si, Ge, Sn, Pb, P, As, Sb, Bi, and La.

5. The composition of claim 2, wherein the metal nitrate comprises at least one selected from the group consisting of aluminum nitrate hydrate, indium nitrate hydrate, zinc nitrate 6-hydrate, zinc nitrate hydrate, yttrium nitrate hydrate, barium nitrate hydrate, lanthanum nitrate hydrate, strontium nitrate hydrate, indium nitrate anhydride, aluminum nitrate anhydride, and zinc nitrate anhydride.

6. The composition of claim 1, further comprising at least one selected from the group consisting of hydrochloric acid, nitric acid, sulfuric acid, acetic acid, ammonium hydroxide, potassium hydroxide, and sodium hydroxide.

7. The composition of claim 1, wherein the molar content of the metal nitrate is about 0.001 M to about 10 M.

8. A method of manufacturing a thin-film transistor, the method comprising:
applying a composition on a substrate to form a thin-film on the substrate, the composition comprising:
a metal nitrate, and
water;
heating the thin-film; and
patterning the thin-film to form an oxide semiconductor pattern,
wherein the potential of hydrogen (pH) of the composition is about 1 to about 4.

9. The method of claim 8, wherein the thin-film is heated at about 100° C. to about 150° C.

10. The method of claim 8, wherein the metal nitrate comprises a hydrate or an anhydride.

11. The method of claim 8, wherein the metal nitrate comprises at least one selected from the group consisting of aluminum nitrate hydrate, indium nitrate hydrate, zinc nitrate 6-hydrate, zinc nitrate hydrate, yttrium nitrate hydrate, barium nitrate hydrate, lanthanum nitrate hydrate, strontium nitrate hydrate, indium nitrate anhydride, aluminum nitrate anhydride, and zinc nitrate anhydride.

12. The method of claim 8, wherein the composition further comprises at least one selected from the group consisting of hydrochloric acid, nitric acid, sulfuric acid, acetic acid, ammonium hydroxide, potassium hydroxide, and sodium hydroxide.

13. The method of claim 10, wherein the molar content of the metal nitrate is about 0.001 M to about 10 M.

14. The method of claim 8, further comprising:
forming an etch stopper on the oxide semiconductor pattern; and
forming a source electrode on the substrate; and
forming a drain electrode spaced apart from the source electrode on the substrate,
wherein at least a portion of the source electrode and at least a portion of the drain electrode overlap respective portions of the etch stopper.

15. The method of claim 8, wherein the composition is applied on the substrate via spin coating, dip coating, bar coating, screen printing, slide coating, roll coating, slit coating, spray coating, dip-penning, nano-dispensing, or inkjet printing.

16. The composition of claim 1, wherein the water is deionized water.

17. The composition of claim 1, wherein the molar content of the metal nitrate is about 0.01 M to about 1 M.

18. The composition of claim 1, further comprising at least one solution stabilizer selected from the group consisting of monoethanol amine, diethanol amine, triethanol amine, monoisopropyl amine, N,N-methylethanol amine, aminoethylethanol amine, diethyleneglycole amine, N-t-butylethanol amine, tetramethylammonium hydroxide, methylamine, ethylamine, and acetylacetone.

19. The composition of claim 1, wherein, based on the total weight of the composition, the composition further comprises from about 0.01% by weight to about 30% by weight of a solution stabilizer.

20. The method of claim 8, wherein the thin-film transistor is part of a semiconductor layer of a display device.
